(19) United States
(12) Patent Application Publication
(10) Pub. No.: US 2021/0328326 A1
(43) Pub. Date: Oct. 21, 2021

(54) TELECOMMUNICATION APPARATUS AND ASSOCIATED METHODS

(71) Applicants: Markku Rouvala, Helsinki (FI); Kai Jämsä, Littoinen (FI); Samuli Wallius, Turku (FI); Tapani von Rauner, Helsinki (FI)

(72) Inventors: Markku Rouvala, Helsinki (FI); Kai Jämsä, Littoinen (FI); Samuli Wallius, Turku (FI); Tapani von Rauner, Helsinki (FI)

(73) Assignee: NOKIA CORPORATION, Espoo (FI)

(21) Appl. No.: 13/812,211

(22) PCT Filed: Jul. 28, 2010
(86) PCT No.: PCT/IB2010/001867

§ 371 Date: May 6, 2015

(51) Int. Cl. H01Q 1/24; H05K 1/16; H05K 1/03; H05K 3/46

(52) U.S. Cl. CPC H01Q 1/243; H05K 1/162; H05K 2201/055; H05K 3/4691; H05K 1/0393

(57) ABSTRACT

An apparatus comprising first and second circuit boards, and an antenna for transmitting and/or receiving electromagnetic signals, the first and second circuit boards each comprising an electrically conductive layer, and a capacitive element configured to be charged and discharged, the apparatus configured such that a chamber is defined between the first and second circuit boards with the capacitive elements contained therein and facing one another, the chamber containing an electrolyte, wherein the electrically conductive layer of the first circuit board is configured to serve as a reference ground for the antenna, and wherein discharge of the capacitive elements is configured to provide a flow of current to an amplifier configured to drive the antenna.

### TECHNICAL FIELD

The present disclosure relates to the field of so-called “supercapacitors” and such like, associated apparatus, methods and computer programs, and in particular concerns the integration of a supercapacitor within a flexible printed circuit (FPC) structure. Certain disclosed example aspects/embodiments relate to portable electronic devices, in particular, so-called hand-portable electronic devices which may be hand-held in use (although they may be placed in a cradle in use). Such hand-portable electronic devices include so-called Personal Digital Assistants (PDAs).

The portable electronic devices/apparatus according to one or more disclosed example aspects/embodiments may provide one or more audio/text/video communication functions (e.g. tele-communication, video-communication, and/or text transmission, Short Message Service (SMS)/Multimedia Message Service (MMS)/emailing functions, interactive/non-interactive viewing functions (e.g. web-browsing, navigation, TV/program viewing functions), music recording/playing functions (e.g. MP3 or other format and/or (FM/AM) radio broadcast recording/playing), downloading/sending of data functions, image capture function (e.g. using a (e.g. in-built) digital camera), and gaming functions.

### BACKGROUND

Multimedia enhancement modules in portable electronic devices (such as camera flash modules, loudspeaker driver modules, and power amplifier modules for electromagnetic transmission) require short power bursts. Typically, electrolytic capacitors are used to power LED and xenon flash modules and conventional capacitors are used to power loudspeaker driver modules, but neither are able to satisfy the power demands needed for optimal performance.

The situation could be improved by the use of supercapacitors. In an LED flash module, for example, double the light output can be achieved using supercapacitors instead of electrolytic capacitors. The problem is not as straight forward as simply switching one type of capacitor for the other, however. In modern electronic devices, miniaturisation is an important factor, and state-of-the-art supercapacitors do not fulfil the size and performance requirements in currently available packaging. Power sources for modules requiring high power bursts have to be implemented close to the load circuit, which for flash and speaker applications means closer than 10-30 mm. Unfortunately, present supercapacitors can be bulky, can suffer from electrolyte swelling, and can have the wrong form factor for attachment to the circuit boards of portable electronic devices. In addition, the attachment of supercapacitors often requires several undesirable stages of processing.

The apparatus and associated methods disclosed herein may or may not address one or more of these issues.

The listing or discussion of a prior-published document or any background in this specification should not necessarily be taken as an acknowledgement that the document or background is part of the state of the art or is common general knowledge. One or more example aspects/embodiments of the present disclosure may or may not address one or more of the background issues.

### SUMMARY

An apparatus comprising first and second circuit boards, and an antenna for transmitting and/or receiving electromagnetic signals,
the first and second circuit boards each comprising an electrically conductive layer, and a capacitive element configured to be charged and discharged, the apparatus configured such that a chamber is defined between the first and second circuit boards with the capacitive elements contained therein and facing one another, the chamber containing an electrolyte,
wherein the electrically conductive layer of the first circuit board is configured to serve as a reference ground for the antenna, and
wherein discharge of the capacitive elements is configured to provide a flow of current to an amplifier configured to drive the antenna.

The apparatus may comprise an amplifier configured to drive the antenna. The amplifier may be electrically connected to the electrically conductive layer of the first circuit board.

The amplifier may be positioned to minimise the distance between the capacitive elements and the amplifier.

The apparatus may form part of an electronic device. The electrically conductive layer of the first circuit board may be electrically connected to at least one grounded part of the electronic device. The electronic device may comprise a motherboard. The first circuit board may comprise part of the motherboard.

The antenna may be one of the following: a monopole, dipole, loop, inverted-F, planar inverted-L, or planar inverted-F antenna. The planar inverted-F antenna may be one end of the first circuit board which has been bent around on itself to define a cavity.

One or both of the first and second circuit boards may be flexible printed circuit boards. One or both of the first and second circuit boards may be flexible regions of a rigid-flex circuit board.

The capacitive elements may be referred to as “electrodes”. Each capacitive element may comprise a high surface area material. Each capacitive element may comprise an electrically conductive region having a surface. The electrically conductive region may comprise one or more of the following materials: copper, aluminium, and carbon. The high surface area material may be disposed on the surface of each electrically conductive region. In each of the example embodiments described herein, the respective surfaces/high surface area materials of the electrically conductive regions may be configured to face one another.

The high surface area material may be electrically conductive. The high surface area material may comprise one or more of the following: nanoparticles, nanowires, nanotubes, nanohorns, nanofibers and nano-onions. In particular, the high surface area material may comprise one or more of the following: activated carbon, carbon nanowires, carbon nanotubes, carbon nanohorns, carbon nanofibres and carbon nano-onions. The carbon nanotubes may be multiple wall carbon nanotubes.

The electrically conductive regions may be configured to maximise adhesion of the high surface area material to the surfaces of the electrically conductive regions. The electrically conductive regions may be configured to minimise the electrical resistance of the capacitive elements. The thickness of the high surface area material may be configured to minimise the electrical resistance of the capacitive elements.

The electrically conductive layers of the first and second circuit boards may be coated on one or both sides with a layer of electrically insulating material. The electrically conductive layers may be electrically connected to the electrically conductive region by one or more of the following: a connector, a vertical interconnect access (VIA) connection, a pogo pin, a solder contact, a wire, and an electrically conductive adhesive (such as an anisotropic conductive adhesive, a pressure setting adhesive or a temperature setting adhesive). The electrically conductive layers may comprise copper.

The layers of electrically insulating material may comprise polyimide. The layers of electrically insulating material may be adhered to the electrically conductive layers by an adhesive. Each of the first and second circuit boards may comprise a layer of surface protection material between the electrically conductive region and the high surface area material. The layer of surface protection material may comprise an organic surface protection (OSP) material.

The first and second circuit boards may be configured to allow the apparatus to be bent through an angle of less than or equal to 180°. The first and second circuit boards may be sufficiently flexible to render the apparatus suitable for use in flex-to-install applications. Formation of the chamber may be configured to increase the rigidity of the first and second circuit boards. For example, each of the first and second circuit boards may have a minimum bending radius of 0.5 mm before formation of the chamber, and a minimum bending radius of 0.2-0.5 cm after formation of the chamber.

The apparatus may be configured to store electrical charge at the interface between the capacitive elements and the electrolyte. The electrolyte may be located between the capacitive elements. The first and second circuit boards may be sealed together to contain the electrolyte within the chamber. The electrolyte may comprise first and second ionic species of opposite polarity. The first and second ionic species may be configured to move towards the capacitive element of the first and second circuit boards, respectively, when a potential difference is applied between the capacitive elements. The electrolyte may be an organic electrolyte. The organic electrolyte may be based on an aprotic solvent such as acetonitrile, or on a carbonate-based solvent such as propylene carbonate. The electrolyte may comprise tetraethylammonium tetrafluoroborate in acetonitrile. The electrolyte may be an aqueous electrolyte. The electrolyte may be chosen such that a potential difference of between 0V and 0.9V may be applied between the capacitive elements without the electrolyte breaking down. Advantageously, the electrolyte may be chosen such that a potential difference of between 0V and 2.7V may be applied between the capacitive elements without the electrolyte breaking down.

The apparatus may comprise a separator between the capacitive elements. The separator may be configured to prevent direct physical contact between the capacitive elements. The separator may comprise one or more pores. The pores in the separator may be configured to allow the first and second ionic species to pass through the separator towards the capacitive elements when the potential difference is applied, thereby facilitating charging of the apparatus. Likewise, the pores in the separator may be configured to allow the first and second ionic species to pass through the separator away from the capacitive elements when the apparatus is used to power an electrical component, thereby facilitating discharging of the apparatus. The separator may comprise one or more of the following: polypropylene, polyethylene, cellulose, and polytetrafluoroethylene. The separator may comprise one, two, three, or more than three layers. Each layer may comprise one or more of the above-mentioned materials.

The apparatus may comprise a power supply configured to apply a potential difference between the capacitive elements. The power supply may comprise first and second terminals of opposite polarity. The electrically conductive layers of the first and second circuit boards may be electrically connected to the first and second terminals of the power supply, respectively.

The apparatus may comprise an electrical connector between the electrically conductive layers of the first and second circuit board. The electrical connector may be configured to enable a flow of electrical charge from the capacitive elements to provide power to one or more electrical components when the apparatus discharges. The one or more electrical components may be physically and electrically connected to the electrically conductive layer of one or both of the first and second circuit boards. The electrical connector may comprise an electrically conductive adhesive. The electrically conductive adhesive may comprise one or more of the following: an anisotropic conductive adhesive, a conductive pressure setting adhesive and a conductive temperature setting adhesive. The electrically conductive adhesive may be further configured to seal the first and second sections together to contain the electrolyte within the chamber. The electrical connector may comprise a metallic interconnector. The metallic interconnector may be a vertical interconnect access (VIA) connector. The apparatus may comprise a switch configured to connect and disconnect the electrical connector/connection. Disconnection of the electrical connector may be configured to allow the apparatus to be charged. Connection of the electrical connector may be configured to allow the apparatus to be discharged. The switch may be located on the first or second circuit board, or within a charger circuit forming part of the circuit board assembly.

According to a further aspect, there is provided a module for a portable electronic device, the module comprising any apparatus described herein. The apparatus may form part of a multimedia enhancement module. The multimedia enhancement module may be a power amplifier module for electromagnetic transmission/reception. The power amplifier module may be a power amplifier module for RF transmission.

According to a further aspect, there is provided a portable electronic device comprising any apparatus described herein. The apparatus may be a portable electronic device, circuitry for a portable electronic device or a module for a portable electronic device. The apparatus may form part of a portable electronic device or part of a module for a portable electronic device. The portable electronic device may be a portable telecommunications device.

According to a further aspect, there is provided a method of assembling an apparatus, the method comprising:
providing first and second circuit boards, the first and second circuit boards each comprising an electrically conductive layer, and a capacitive element configured to be charged and discharged,
configuring the first and second circuit boards to define a chamber therebetween with the capacitive elements contained therein and facing one another;
providing an electrolyte within the chamber; and
providing an antenna to form an apparatus, the apparatus comprising first and second circuit boards, and an antenna for transmitting and/or receiving electromagnetic signals, wherein the electrically conductive layer of the first circuit board is configured to serve as a reference ground for the antenna, and wherein discharge of the capacitive elements is configured to provide a flow of current to an amplifier configured to drive the antenna.

According to a further aspect, there is provided a method of powering an amplifier configured to drive an antenna, the method comprising:
using an apparatus, the apparatus comprising first and second circuit boards, and an antenna for transmitting and/or receiving electromagnetic signals,
the first and second circuit boards each comprising an electrically conductive layer, and a capacitive element configured to be charged and discharged, the apparatus configured such that a chamber is defined between the first and second circuit boards with the capacitive elements contained therein and facing one another, the chamber containing an electrolyte,
wherein the electrically conductive layer of the first circuit board is configured to serve as a reference ground for the antenna, and
wherein discharge of the capacitive elements is configured to provide a flow of current to an amplifier configured to drive the antenna; and wherein the method comprises
discharging the capacitive elements to provide a flow of current to the amplifier configured to drive the antenna.

The steps of any method disclosed herein do not have to be performed in the exact order disclosed, unless explicitly stated.

According to a further aspect, there is provided a computer program for controlling the power supply of an amplifier configured to drive an antenna using an apparatus, the apparatus comprising first and second circuit boards, and an antenna for transmitting and/or receiving electromagnetic signals,
the first and second circuit boards each comprising an electrically conductive layer, and a capacitive element configured to be charged and discharged, the apparatus configured such that a chamber is defined between the first and second circuit boards with the capacitive elements contained therein and facing one another, the chamber containing an electrolyte,
wherein the electrically conductive layer of the first circuit board is configured to serve as a reference ground for the antenna, and
wherein discharge of the capacitive elements is configured to provide a flow of current to an amplifier configured to drive the antenna,
the computer program comprising code configured to control discharge of the capacitive elements to provide a flow of current to the amplifier configured to drive the antenna.

The apparatus may comprise a processor configured to process the code of the computer program. The processor may be a microprocessor, including an Application Specific Integrated Circuit (ASIC).

The present disclosure includes one or more corresponding aspects, example embodiments or features in isolation or in various combinations whether or not specifically stated (including claimed) in that combination or in isolation. Corresponding means for performing one or more of the discussed functions are also within the present disclosure.

Corresponding computer programs for implementing one or more of the methods disclosed are also within the present disclosure and encompassed by one or more of the described example embodiments.

The above summary is intended to be merely exemplary and non-limiting.

### BRIEF DESCRIPTION OF THE FIGURES

A description is now given, by way of example only, with reference to the accompanying drawings, in which:—

FIG. 1a illustrates schematically a conventional capacitor;

FIG. 1b illustrates schematically an electrolytic capacitor;

FIG. 1c illustrates schematically an embodiment of a so-called supercapacitor;

FIG. 2 illustrates schematically (in cross section) a supercapacitor integrated within a flexible printed circuit structure;

FIG. 3a illustrates schematically the flexible printed circuit structure of FIG. 2 configured to define a chamber between the first and second circuit boards;

FIG. 3b illustrates schematically the flexible printed circuit structure of FIG. 3a in plan view;

FIG. 4 illustrates schematically the flexible printed circuit structure of FIG. 3a in operation;

FIG. 5a illustrates schematically charging of the flexible printed circuit structure;

FIG. 5b illustrates schematically discharging of the flexible printed circuit structure;

FIG. 6a illustrates schematically an electrical connector comprising a metallic interconnector;

FIG. 6b illustrates schematically an electrical connector comprising an electrically conductive adhesive;

FIG. 6c illustrates schematically a flexible printed circuit structure in origami flex form;

FIG. 7a illustrates schematically an unbent rigid-flex circuit board in plan view;

FIG. 7b illustrates schematically an unbent rigid-flex circuit board in side view;

FIG. 7c illustrates schematically a bent rigid-flex circuit board in side view;

FIG. 8a illustrates schematically (in cross-section) a supercapacitor integrated within a rigid-flex circuit board;

FIG. 8b illustrates schematically the rigid-flex circuit structure of FIG. 8a in operation;

FIG. 9a illustrates schematically a first method of assembling the rigid-flex integrated supercapacitor of FIG. 8;

FIG. 9b illustrates schematically a second method of assembling the rigid-flex integrated supercapacitor of FIG. 8;

FIG. 9c illustrates schematically a third method of assembling the rigid-flex integrated supercapacitor of FIG. 8;

FIG. 9d illustrates schematically a fourth method of assembling the rigid-flex integrated supercapacitor of FIG. 8;

FIG. 10a illustrates schematically two flexible printed circuit structures connected in series;

FIG. 10b illustrates schematically two flexible printed circuit structures connected in parallel;

FIG. 10c illustrates schematically a first configuration in which two circuit boards are combined in origami flex form to create a stack of integrated supercapacitors;

FIG. 10d illustrates schematically a second configuration in which two circuit boards are combined in origami flex form to create a stack of integrated supercapacitors;

FIG. 11a illustrates schematically a planar monopole antenna in plan view;

FIG. 11b illustrates schematically a planar monopole antenna in side view;

FIG. 12a illustrates schematically a microstrip antenna in plan view;

FIG. 12b illustrates schematically a microstrip antenna in side view;

FIG. 13a illustrates schematically a planar inverted-F antenna comprising a dielectric material between the ground plane and antenna;

FIG. 13b illustrates schematically a planar inverted-F antenna comprising an air cavity between the ground plane and antenna;

FIG. 14a illustrates schematically a planar monopole antenna integrated with a supercapacitor;

FIG. 14b illustrates schematically a planar inverted-F antenna integrated with a supercapacitor;

FIG. 14c illustrates schematically an origami-flex structure comprising a planar inverted-F antenna integrated with a supercapacitor;

FIG. 15a illustrates schematically the configuration of an antenna and amplifier with battery power source;

FIG. 15b illustrates schematically the configuration of an antenna and amplifier with discrete supercapacitor power source;

FIG. 15c illustrates schematically a typical configuration of an antenna and amplifier with integrated supercapacitor power source;

FIG. 16 illustrates schematically a device comprising the apparatus described herein;

FIG. 17 illustrates schematically a computer readable media providing a program;

FIG. 18 illustrates schematically a method of assembling an antenna integrated with a supercapacitor; and

FIG. 19 illustrates schematically a method of powering an amplifier configured to drive an antenna using an integrated supercapacitor.

### DESCRIPTION

In electrical circuits, batteries and capacitors are used to provide other components with electrical power. These power supplies operate in completely different ways, however. Batteries use electrochemical reactions to generate electricity. They comprise two electrical terminals (electrodes) separated by an electrolyte. At the negative electrode (the anode), an oxidation reaction takes place which produces electrons. These electrons then flow around an external circuit from the anode to the positive electrode (the cathode) causing a reduction reaction to take place at the cathode. The oxidation and reduction reactions may continue until the reactants are completely converted.

Importantly though, unless electrons are able to flow from the anode to the cathode via the external circuit, the electrochemical reactions cannot take place. This allows batteries to store electricity for long periods of time.

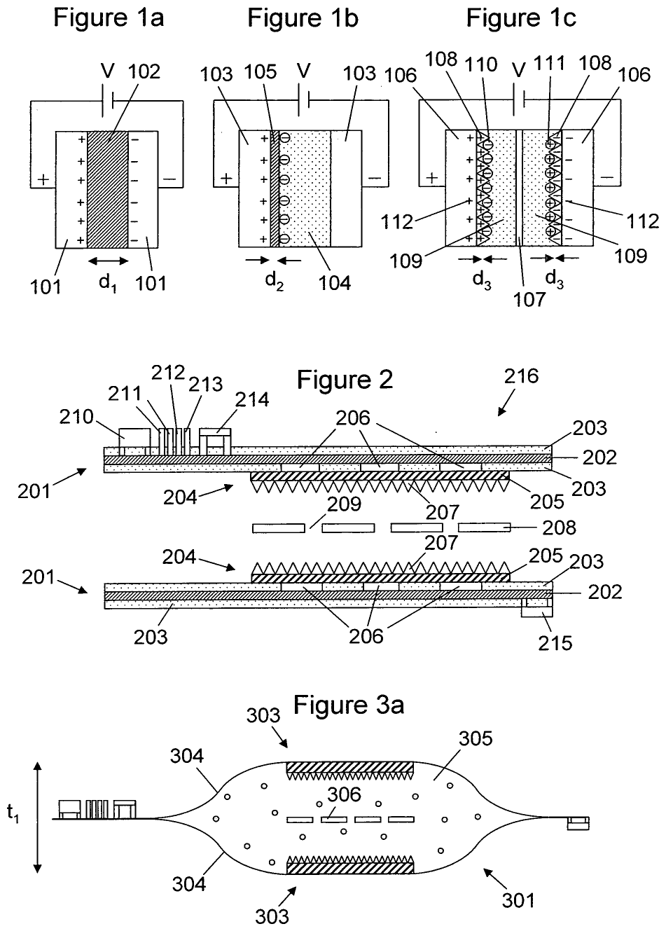

In contrast, capacitors store charge electrostatically, and are not capable of generating electricity. A conventional capacitor (FIG. 1a) comprises a pair of electrical plates 101 separated by an electrical insulator 102. When a potential difference is applied between the plates 101, positive and negative electrical charges build up on opposite plates. This produces an electric field across the insulator 102 which stores electrical energy. The amount of energy stored is proportional to the charge on the plates, and inversely proportional to the separation of the plates, d₁. Therefore, the energy storage of a conventional capacitor can be increased by increasing the size of the plates 101 or by reducing the thickness of the insulator 102. Device miniaturisation governs the maximum plate size, whilst material properties dictate the minimum insulator thickness that can be used without conduction of the insulator 102 (breakdown).

Electrolytic capacitors (FIG. 1b) use a special technique to minimise the plate spacing, d₂. They consist of two conductive plates 103 separated by a conducting electrolyte 104. When a potential difference is applied, the electrolyte 104 carries charge between the plates 103 and stimulates a chemical reaction at the surface of one of the plates. This reaction creates a layer of insulating material 105 which prevents the flow of charge. The result is a capacitor with an ultrathin dielectric layer 105 separating a conducting plate 103 from a conducting electrolyte 104. In this configuration, the electrolyte 104 effectively serves as the second plate. Since the insulating layer 105 is only a few molecules thick, electrolytic capacitors are able to store a greater amount of energy than conventional parallel plate capacitors.

A third type of capacitor, known as a supercapacitor (FIG. 1c), allows even greater energy storage. Supercapacitors (also known as electric double layer capacitors, ultracapacitors, pseudocapacitors and electrochemical double layer capacitors) have similarities to both electrolytic and conventional capacitors. Like a conventional capacitor, a supercapacitor has two electrically conducting plates 106 that are separated by a dielectric material (a separator) 107. The plates 106 are coated in a porous material 108 such as powdered carbon to increase the surface area of the plates 106 for greater charge storage. Like an electrolytic capacitor (and also a battery), a supercapacitor contains an electrolyte 109 between the conducting plates 106. When a potential difference is applied between the plates, the electrolyte 109 becomes polarised. The potential on the positive plate attracts the negative 110 ions in the electrolyte 109, and the potential on the negative plate attracts the positive ions 111. The dielectric separator 107 is used to prevent direct physical contact (and therefore electrical contact) between the plates 106. The separator 107 is made from a porous material to allow the ions 110, 111 to flow towards the respective plates 106.

Unlike batteries, the applied potential is kept below the breakdown voltage of the electrolyte 109 to prevent electrochemical reactions from taking place at the surface of the plates 106. For this reason, a supercapacitor cannot generate electricity like an electrochemical cell. Also, without electrochemical reactions taking place, no electrons are generated. As a result, no significant current can flow between the electrolyte 109 and the plates 106. Instead, the ions 110, 111 in solution arrange themselves at the surfaces of the plates 106 to mirror the surface charge 112 and form an insulating “electric double layer”. In an electric double layer (i.e. a layer of surface charge 112 and a layer of ions 110, 111), the separation, d₃, of the surface charges 112 and ions 110, 111 is on the order of nanometers. The combination of the electric double layer and the use of a high surface area material 108 on the surface of the plates 106 allow a huge number of charge carriers to be stored at the plate-electrolyte interface.

Activated carbon is not the most suitable material 108 for coating the plates 106 of the capacitor, however. The ions 110, 111 in solution are relatively large in comparison to the pores in the carbon, and this limits the energy storage considerably. Recent research in this area has focused on the use of carbon nanotubes and carbon nanohorns instead, both of which offer higher useable surface areas than activated carbon.

Supercapacitors have several advantages over batteries, and as a result, have been tipped to replace batteries in many applications. They function by supplying large bursts of current to power a device and then quickly recharging themselves. Their low internal resistance, or equivalent series resistance (ESR), permits them to deliver and absorb these large currents, whereas the higher internal resistance of a traditional chemical battery may cause the battery voltage to collapse. Also, whilst a battery generally demands a long recharging period, supercapacitors can recharge very quickly, usually within a matter of minutes. They also retain their ability to hold a charge much longer than batteries, even after multiple rechargings. When combined with a battery, a supercapacitor can remove the instantaneous energy demands that would normally be placed on the battery, thereby lengthening the battery lifetime.

Whereas batteries often require maintenance and can only function well within a small temperature range, supercapacitors are comparatively maintenance-free and perform well over a broad temperature range. Supercapacitors also have longer lives than batteries, and are built to last until at least the lifetime of the electronic devices they are used to power. Batteries, on the other hand, typically need to be replaced several times during the lifetime of a device.

Supercapacitors are not without their drawbacks, however. Despite being able to store a greater amount of energy than conventional and electrolytic capacitors, the energy stored by a supercapacitor per unit weight is considerably lower than that of an electrochemical battery. In addition, the working voltage of a supercapacitor is limited by the electrolyte breakdown voltage, which is not as issue with batteries.

As mentioned earlier, existing supercapacitors can be bulky, can suffer from electrolyte swelling and may not have the optimum form factor for attachment to the circuit boards of portable electronic devices. Furthermore, the attachment of existing supercapacitors to circuit boards often requires several stages of processing, thereby rendering them impractical. There will now be described an apparatus and associated methods that may or may not overcome one or more of these issues.

In FIG. 2, there is illustrated a supercapacitor integrated within a flexible printed circuit (FPC) structure 216. The use of an FPC structure 216 provides a “flex-to-install solution”. Flex-to-install refers to a circuit which is bent or folded during device assembly, but which undergoes minimal flexing during the lifetime of the device. If the FPC structure 216 is sufficiently durable, it may also be suitable for dynamic flex applications in which the circuit board is required to bend both during and after device assembly.

The apparatus consists of two FPC boards 201, each comprising a layer of electrically conductive material 202. In this embodiment, the layer of electrically conductive material 202 on each FPC board 201 is coated on either side by a layer of electrically insulating material 203. Subtraction of the insulating material 203 is used to define conductive traces in the electrically conductive material 202. The insulating material 203 is also used to protect the electrically conductive material 202 from the external environment.

Each FPC board 201 further comprises a capacitive element 204 with an electrically conductive region 205. The electrically conductive regions 205 are electrically connected to the layers of electrically conductive material 202, e.g. by vertical interconnect access (VIA) connections 206. The capacitive elements 204 also comprise a high surface area material 207 on top of the electrically conductive regions 205, the material 207 comprising a mixture of one or more of activated carbon (AC), multiple wall carbon nanotubes (MWNTs), carbon nanohorns (CNHs), carbon nanofibers (CNFs) and carbon nano-onions (CNOs). AC, MWNTs, CNHs, CNFs and CNOs are used because of their large electrical conductivity and high surface area. As mentioned earlier, the high surface area allows adsorption of large numbers of electrolyte ions onto the surface of the capacitive elements 204.

The high surface area material 207 may be prepared by mixing different proportions of AC, MWNTs and CNHs together using polytetrafluoroethylene (PTFE) as a binder and acetone as a solvent, and homogenising the mixture by stirring. Following this, the resulting slurry is applied by rolling the mixture onto the surface of each electrically conductive region 205. The FPC boards 201 are then annealed at 50° C. for 20 minutes to drive off the solvent and consolidate the mixture. To maximise its surface area and electrical conductivity, the high surface material 207 is applied to the electrically conductive regions 205 as a thin film.

As shown in FIG. 2, the FPC boards 201 are configured such that the electrically conductive regions 205 (now coated in the high surface area material 207) are facing one another, sandwiching a thin dielectric separator 208 therebetween. The separator 208 prevents direct physical contact (and therefore electrical contact) between the capacitive elements 204, but comprises a number of pores 209 to enable the ions of the electrolyte to move towards the high surface area material 207 when a potential difference has been applied between the capacitive elements 204.

The electrically conductive regions 205 may be formed from a variety of different materials, but advantageously are made from copper, aluminium or carbon. The choice of material affects the physical and electrical properties of the supercapacitor. Copper, and to a lesser extent aluminium, exhibit favourable electrical conductivity. This is advantageous because it allows charge carriers from the electrically conductive material 202 to flow through the electrically conductive region 205 to the high surface area material 207 with minimum resistance. On the other hand, carbon offers better adhesion to the high surface area material 207 than copper and aluminium, and is more cost effective. Carbon also provides a low resistance (ESR) path between the electrically conductive region 205 and the high surface area material 207. Using carbon, supercapacitors with an ESR of ˜3Ω can be produced. Furthermore, the resistance between the electrically conductive material 202 and the electrically conductive region 205 may be reduced by increasing the number or size of the electrical connections (VIAs) 206. The resistance may also be reduced by removing insulating material 203 adjacent the electrically conductive region 205 such that electrically conductive region 205 can be deposited directly onto the electrically conductive material 202. The electrically conductive regions 205 may also comprise a surface finish (coating) to protect the electrically conductive regions 205 or to modify their structural or material properties. Possible surface materials include nickel-gold, gold, silver, or an organic surface protection (OSP) material.

As mentioned in the background section, supercapacitors may be used to power multimedia enhancement modules in portable electronic devices. For modules that require high power bursts, such as LED flash modules, the supercapacitor needs to be implemented close to the load circuit. In the present case, the FPC structure 216 (within which the supercapacitor is integrated) forms the multimedia enhancement module, with the various components of the module physically (and electrically) connected to the FPC boards 201. In FIG. 2, a surface mounted (SMD) LED 210, two ceramic caps 211, an indicator LED 212, an inductor 213, and a supercapacitor charger and LED driver circuit 214 are (electrically) connected to the electrically conductive material 202 of the upper FPC board 201, whilst a board-to-board (B2B) connector 215 is (electrically) connected to the electrically conductive material 202 of the lower FPC board 201. The various electrical components may be soldered or ACF (anisotropic conductive film) contacted to the FPC boards 201. The electrically conductive materials 202 are used to route power to and from the supercapacitor and module components, and the B2B connector 215 (electrically) connects the FPC structure 216 to the main board of the electronic device.

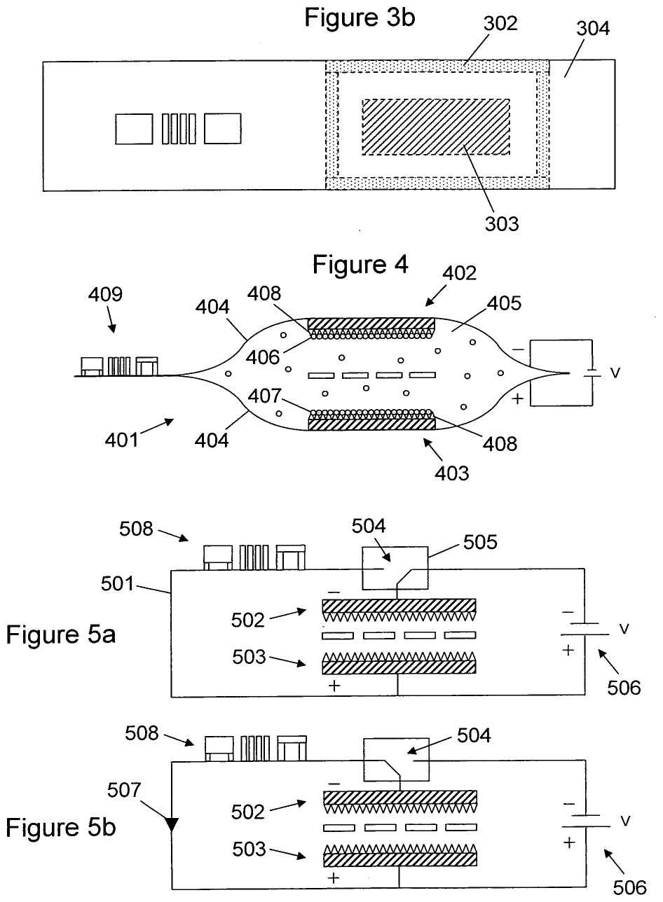

An electrolyte is required between the capacitive elements 204 to enable the storage of electrical charge. To achieve this, the FPC boards 201 are configured to form a chamber within which the electrolyte can be contained. The chamber is illustrated in cross-section in FIG. 3a, and in plan view in FIG. 3b. To create the chamber 301, a border 302 around the capacitive elements 303 is defined (shown in plan view). The FPC boards 304 are then sealed together at the border 302 to prevent the electrolyte 305 (which may be a gel or liquid-type electrolyte) from leaking out or evaporating during use. The FPC boards 304 may be sealed by heat lamination, vacuum packing or standard FPC punching processes. A small region (not shown) of the border 302 may remain unsealed until the electrolyte 305 has been introduced into the chamber 301.

In another embodiment, a ring may be incorporated into the FPC structure to form a chamber. In this embodiment (not shown), the ring is positioned around the capacitive elements 303 and sandwiched between the FPC boards 304. In practise, this may involve placing a first FPC board face-up on a flat surface; placing the ring (which has a diameter of at least the largest in-plane dimension of the capacitive elements 303) around the capacitive element of this FPC board; sealingly attaching the ring to the FPC board; filling the ring with electrolyte 305; placing a second FPC board face-down on top of the first FPC board such that the capacitive element of the second FPC board is contained within the ring and facing the other capacitive element; and sealingly attaching the second FPC board to the ring. Ideally, the thickness of the ring should be substantially the same as the total thickness of the FPC structure. Nevertheless, due to the flexibility of the FPC boards 304, the ring thickness may deviate from the total thickness of the FPC structure and still allow formation of the chamber.

In another embodiment, the ring may comprise an aperture. In this embodiment, the electrolyte may be introduced to the chamber via the aperture and subsequently sealed to retain the electrolyte 305.

It should be noted, however, that the thickness, t₁, of the chamber 301 is exaggerated in FIG. 3a. In practice, the capacitive elements 303 and separator 306 are in physical contact to minimise the thickness of the chamber 301. In another embodiment, the capacitive elements 303 may simply be spaced apart from one another. This configuration would remove the need for a separator 306, but may be difficult to maintain if the FPC structure is physically flexible.

To charge the apparatus, a potential difference is applied across the capacitive elements 402, 403 (FIG. 4). This is performed by connecting the positive and negative terminals of a battery (or other power supply) to the electrically conductive layers of the respective FPC boards 404. In practice, however, the electrically conductive layers of the FPC boards 404 would typically be connected to a charger circuit (not shown) which itself is connected to the battery or other power supply. Application of the potential difference polarises the electrolyte 405, causing adsorption of the positive 406 and negative 407 ions onto the exposed surfaces of the high surface area material 408 of the negatively 402 and positively 403 charged capacitive elements, respectively. The charge stored at the interface between the high surface area material 408 and the electrolyte 405 can be used to power the components of the multimedia enhancement module 409 when the supercapacitor discharges.

A variety of different configurations may be used to discharge the apparatus. In one configuration (shown in FIG. 5), an electrical connector 501 is provided between the electrically conductive layers of the FPC boards. The electrical connector 501 allows electrons to flow from the negatively charged capacitive element 502 to the positively charged capacitive element 503. To prevent this flow of electrons when the apparatus is charging, however, the apparatus may include a switch 504 configured to connect and disconnect the electrical connector 501 (i.e. make or break the connection). Disconnection of the electrical connector 501 allows the apparatus to be charged, whilst connection of the electrical connector 501 allows the apparatus to be discharged. The switch 504 may be provided within a charger circuit 505. When the switch 504 is in a first position (FIG. 5a), it connects the apparatus to the power supply 506, allowing the capacitive elements 502, 503 to be charged. Once the capacitive elements 502, 503 have been charged, movement of the switch 504 to a second position (FIG. 5b) disconnects the apparatus from the power supply 506 and connects the capacitive elements 502, 503 to the electrical components 508. This allows electrons to flow 507 from the negatively charged capacitive element 502 to the positively charged capacitive element 503, thereby discharging the apparatus. The electrical components 508 may be electrically connected to the electrically conductive layers of one or both of the FPC boards. Once the apparatus has been discharged, movement of the switch 504 back to the first position again (FIG. 5a) causes the power supply 506 to recharge the apparatus. A person skilled in the art will appreciate that there are other ways of configuring the circuit to charge and discharge the apparatus, the configuration shown in FIG. 5 constituting just one possible implementation.

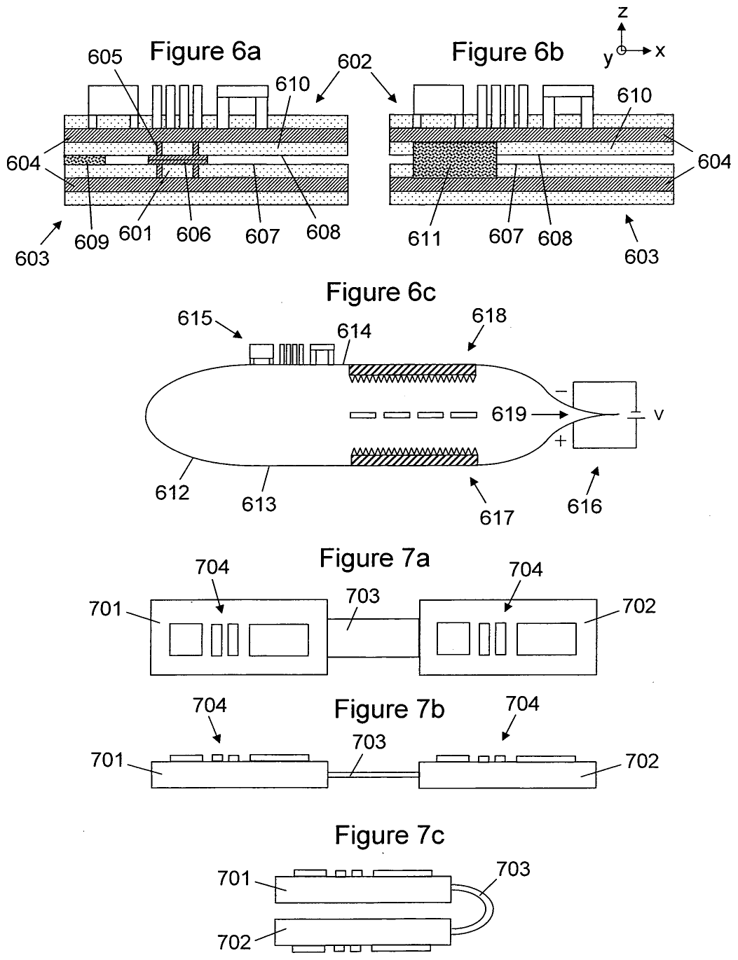

As illustrated in FIG. 6a, the electrical connector may comprise a metallic interconnector such as a vertical interconnect access (VIA) connector. To form this connector, holes 601 are made in the insulating material 610 of each FPC board 602, 603 (possibly by drilling) to reveal the electrically conductive layers 604 (from which the bus lines of the FPC boards 602, 603 are formed). The internal surface of each hole 601 is then plated with an electrically conductive coating 605 (typically a metal such as copper) using a partial plating process such that the electrically conductive material 605 is in electrical contact with the electrically conductive layer 604. Alternatively, the holes 601 may be filled with electrically conductive material, rings or rivets to form the electrical connection. Electrically conductive pads 606 are then deposited on the top surface 607 and bottom surface 608 of the bottom 603 and top 602 FPC boards, respectively, in electrical contact with the electrically conductive coating 605 of each hole 601. The pads 606 may be formed using a lithographic procedure, but could be formed using the plating/filling process by simply extending deposition of the electrically conductive coating 605 from within the holes 601 to the surfaces 607, 608 of the FPC boards 602, 603. Once the pads 606 have been formed, the FPC boards 602, 603 are positioned one on top of the other. The holes 601 of the top FPC board 602 are aligned with the holes 601 of the bottom FPC board 603 so that the pads 606 on the top surface 607 of the bottom FPC board 603 are in physical and electrical contact with the pads 606 on the bottom surface 608 of the top FPC board 602. In this way, the pads 606 and electrically conductive coating 605 of both FPC boards 602, 603 form an electrical path between the electrically conductive layers 604. In order to maintain the alignment (and therefore electrical connection), however, the FPC boards 602, 603 must be held in place. This may be achieved using an adhesive 609 between the FPC boards 602, 603 to prevent movement therebetween.

The plating process (possibly with additional lithography to form the pads) described above is time consuming, labour intensive and expensive. It is also technically difficult to implement. A more efficient process for forming the electrical connector will now be described with reference to FIG. 6b.

Anisotropic conductive adhesive (ACA), encompassing both anisotropic conductive film (ACF) and anisotropic conductive paste (ACP), is a lead-free and environmentally friendly interconnect system commonly used in liquid crystal display (LCD) manufacturing to make electrical and mechanical connections from the driver electronics to the glass substrates of the LCD. It has more recently been used to form the flex-to-board or flex-to-flex connections used in handheld electronic devices such as mobile phones, MP3 players, or in the assembly of CMOS camera modules. The material consists of an adhesive polymer containing electrically conductive particles.

ACA may be applied to the surfaces of the FPC boards to form an electrical connection. To achieve this, the electrically conductive layers 604 must first be exposed. This is performed by removing some of the insulating material 610 above and below the electrically conductive layers 604 of the bottom 603 and top 602 FPC boards, respectively (possibly by drilling). Once the electrically conductive layers 604 are exposed, ACA 611 is deposited on the top surface 607 of the bottom FPC board 603 in physical contact with the exposed material of the electrically conductive layers 604. This may be done using a lamination process for ACF, or either a dispense or printing process for ACP. The top FPC board 602 is then placed in position over the bottom FPC board 603 (i.e they are aligned with one another), and the two FPC boards 602, 603 are pressed together to mount the top FPC board 602 on the bottom FPC board 603. Mounting may be performed using no heat, or using just enough heat to cause the ACA 611 to become slightly tacky.

Using Hitachi™ chemical AC2051/AC2056 as the ACA, the temperature, pressure and time parameters required to successfully mount the top FPC board 602 on the bottom FPC board 603 are 80° C., 10 kgf/cm² and 5 secs, respectively. Using 3M™ ACF 7313 as the ACA, the temperature, pressure and time parameters are 100° C., 1-15 kgf/cm² and 1 sec, respectively.

Bonding is the final stage in the process required to complete the ACA assembly. During lamination and mounting, the temperature may range from ambient to 100° C. with the heat applied for 1 second or less. In order to bond the FPC boards 602, 603 together, however, a greater amount of thermal energy is required, firstly to cause the ACA 611 to flow (which allows the FPC boards 602, 603 to be positioned for maximum electrical contact), and secondly to cure the ACA 611 (which allows a lasting and reliable bond to be created). Depending on the specific ACA and FPC materials used, the required temperature and heating time may range from 130−220° C. and 5-20 secs, respectively. Bonding is performed by pressing a bonding tool head (not shown) onto the top FPC board 602. The tool head is maintained at the required temperature and is applied to the top FPC board 602 at the required pressure for the required period of time. The required pressure may range from 1-4 MPa (˜10-40 kgf/cm²) over the entire area under the tool head.

Using Hitachi™ chemical AC2051/AC2056 as the ACA, the temperature, pressure and time parameters required to successfully bond the top FPC board 602 to the bottom FPC board 603 are 170° C., 20 kgf/cm² and 20 secs, respectively. Using 3M™ ACF 7313 as the ACA, the temperature, pressure and time parameters are 140° C., 15 kgf/cm² and 8-12 secs, respectively.

When the ACA 611 is compressed, the electrically conductive particles contained within the adhesive polymer are forced into physical contact with one another, thereby creating an electrical path from the electrically conductive layer 604 of the top FPC board 602 to the electrically conductive layer 604 of the bottom FPC board 603. The electrical path is highly directional (hence anisotropic conductive adhesive). It allows current to flow in the z-axis, but prevents the flow of current in the x-y plane. This feature is important in the present apparatus, because it prevents (or minimises) electrical shorting of the electrolyte. As the ACA 611 cures, the electrically conductive particles are fixed in the compressed form, thereby maintaining good electrical conductivity in the z-axis.

Rather than having to apply heat to bond the FPC boards together, a conductive pressure setting adhesive (PSA) may be used instead. A PSA is an adhesive which forms a bond with an adherend under pressure alone. It is used in pressure setting tapes, labels, note pads, automobile trim, and a wide variety of other products. As the name suggests, the degree of bonding is influenced by the amount of pressure applied, but surface factors such as smoothness, surface energy, contaminants, etc can also affect adhesion. PSAs are usually designed to form and maintain a bond at room temperature. The degree of adhesion and shear holding ability often decrease at low temperatures and high temperatures, respectively. Nevertheless, special PSAs have been developed to function at temperatures above and below room temperature. It is therefore important to use a PSA formulation that is suitable for use at the typical operating temperatures of the electronic circuitry.

As described previously, the FPC boards need to be sealed together in order to form the chamber and prevent the electrolyte from escaping. An electrically conducting or non-conducting adhesive may be used for this purpose. In one embodiment, the ACA or conducting PSA used to provide the electrical connection between the FPC boards could also be used to seal the structure. In this configuration, the fabrication procedures of providing the electrical connection and sealing the structure are combined as a single procedure. In another embodiment, the procedure of providing the electrical connector may be performed separately from the procedure of sealing the structure. In this latter embodiment, either the same or different adhesives could be used for each procedure.

It will be appreciated that, in certain embodiments (as shown in FIG. 6c), a single FPC board 612 may be bent around onto itself to define the chamber, rather than two separate FPC boards 602, 603 being used (although one side of the structure 619 will still need to be sealed to contain the electrolyte). This configuration is referred to as the “origami flex form”. An advantage of the origami flex form is that the electrically conductive layer 604 is continuous from one side 613 (i.e. bottom FPC 603) of the structure to the other side 614 (i.e. top FPC 602). This feature negates the need to provide an additional electrical connector between the FPC boards 602, 603 in order to power the electrical components 615. Again, to control charging and discharging of the apparatus, a switch (not shown) is required to make and break the electrical connection, otherwise the charge will simply flow around the circuit between the opposite terminals of the battery 616 (or other power supply) without being stored at the capacitive elements 617, 618.

Integration of the supercapacitor within the FPC structure increases the possibility of distributed local capacitor placement. This feature enables power to be received from local sources without the resistive and inductive losses caused by electrical junctions (e.g. connectors, vias, pogo pins, solder contacts etc). Supercapacitor integration also reduces the number of manufacturing processes in the assembly phase.

As described previously, the multimedia enhancement module needs to be connected to the main board of the electronic device. With rigid and flexible circuit boards, this is usually achieved with a board-to-board (B2B) connector (215 in FIG. 2). To simplify the assembly process further, however, the supercapacitor could be integrated within a rigid-flex circuit board instead. As shown in FIG. 7a (plan view) and FIG. 7b (side view), rigid-flex circuit boards comprise two or more rigid regions 701, 702 which are physically and electrically connected to one another by flexible regions 703. The various electrical components 704 of the circuit are usually connected to the rigid regions 701, 702, with the flexible regions 703 used simply to route power and/or signals between the rigid regions 701, 702. The presence of the flexible regions 703 allows the rigid-flex board to be bent to fit different shapes and sizes of device casing. FIG. 7c shows a rigid-flex circuit board folded in half with one rigid region 701 positioned above another rigid region 702.

The rigid regions 701, 702 of a rigid-flex circuit board may be used to form the main board and multimedia enhancement module, respectively, thereby obviating the need for a B2B connector. In addition, the supercapacitor may be integrated within a flexible region 703 of the rigid-flex circuit board, thus freeing up space on the rigid regions 701, 702 for other electrical components 704. Furthermore, given that rigid-flex circuit boards can be bent about the flexible region 703 (in some cases through an angle of up to 180°), they are well-suited to flex-to-install and/or dynamic flex applications.

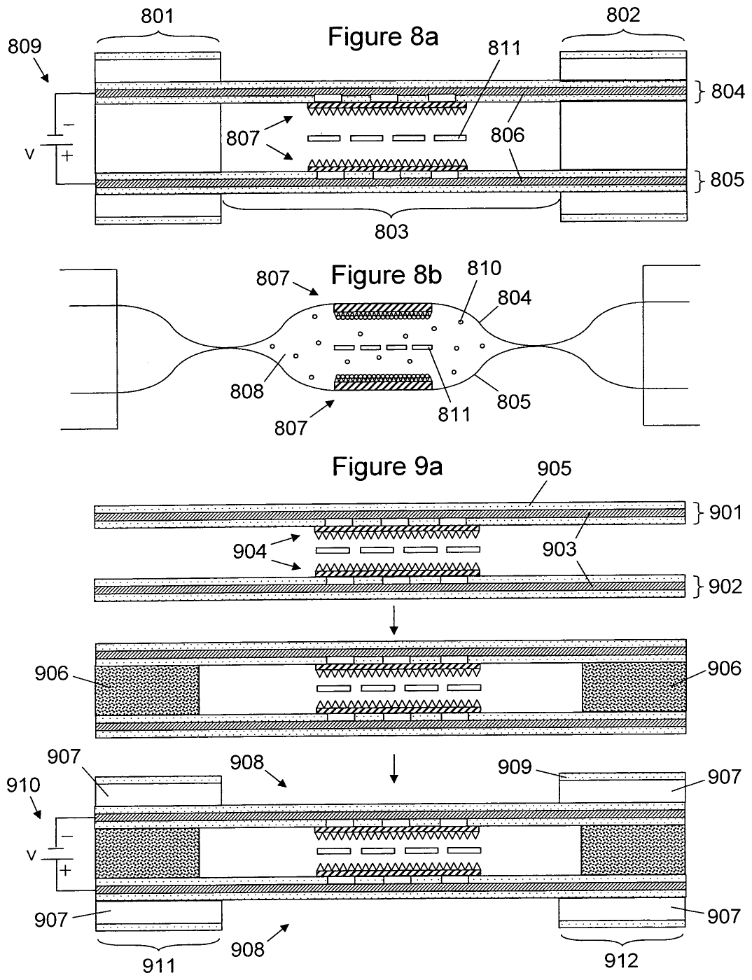

A rigid-flex integrated supercapacitor is shown in FIG. 8a prior to full assembly. The structure comprises first 801 and second 802 rigid regions connected by a flexible (intermediate) region 803, the flexible region 803 comprising first 804 and second 805 sections each comprising an electrically conductive layer 806 and a capacitive element 807. It should be noted, however, that the first 804 and second 805 sections continue from the flexible region 803 of the structure into the rigid regions 801, 802. As illustrated in FIG. 8b, the first 804 and second 805 sections are sealed to define a chamber 808 with the capacitive elements 807 contained therein and facing one another. An electrolyte 810 and separator 811 are also required, as previously described. In order to charge the capacitive elements 807, the positive and negative terminals of the power supply 809 need to be connected to the electrically conductive layers 806 of the first 804 and second 805 sections, respectively. In the configuration shown, the electrically conductive layers 806 of the flexible region 803 extend into the rigid regions 801, 802. In this way, by connecting the positive and negative terminals of the power supply 809 to the electrically conductive layers 806 at one of the rigid regions 801, 802, the capacitive elements 807 can be charged.

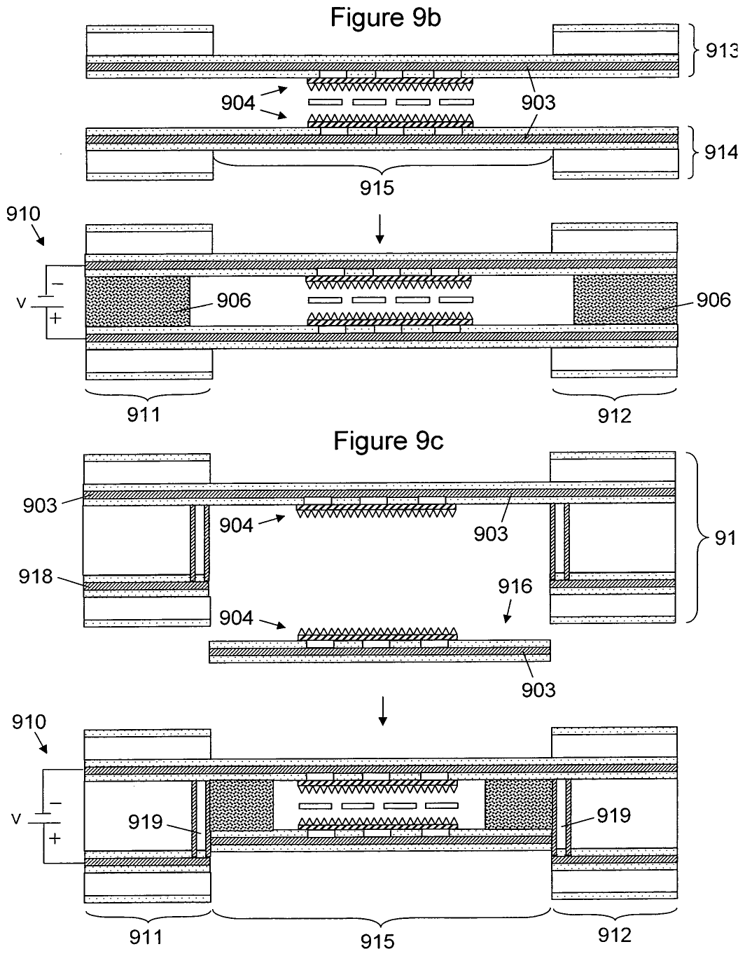

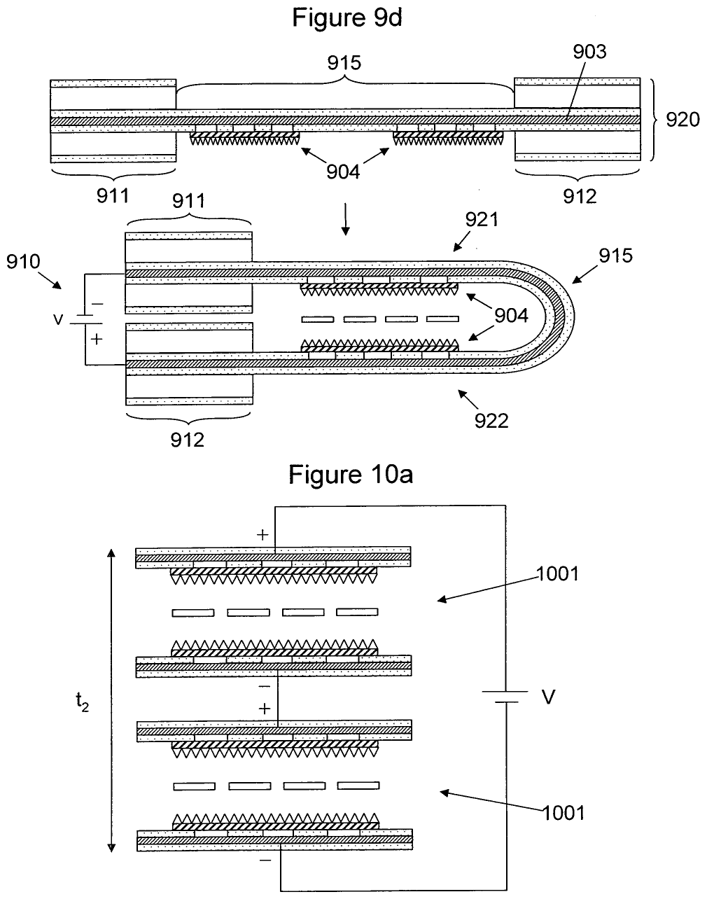

A number of different methods may be used to assemble a rigid-flex integrated supercapacitor, four of which will now be described with respect to FIGS. 9a-d. The skilled person will appreciate that the structures and processes described serve merely as examples, and are by no means the only possible options.

In each of the example embodiments described below, the first and second sections of the flexible region are sealed together to define a chamber, within which the capacitive elements, the electrolyte, and the separator are contained. This is necessary to prevent the electrolyte from escaping. The electrolyte may be a solid or gel electrolyte, in which case the electrolyte may be added before the first and second sections are sealed at all, or may be a liquid electrolyte, in which case a small hole may be left unsealed for injection of the electrolyte before the structure is sealed completely. As described previously, the separator is configured to prevent direct electrical contact between the capacitive elements.

One method of assembly is shown in FIG. 9a. First 901 and second 902 flexible sections (which may be FPC boards as described with respect to FIG. 2) are provided, each comprising an electrically conductive layer 903 and a capacitive element 904. The capacitive elements 904 may be formed as described with reference to FIG. 2. The electrically conductive layers 903 may be coated on one or both sides by a layer of electrically insulating material 905 (such as polyimide). The electrically insulating material 905 provides electrical isolation and protection for each electrically conductive layer 903. The first 901 and second 902 flexible sections are then bonded to one another. This may be achieved by applying an adhesive 906 (such as an anisotropic conductive adhesive, a pressure setting adhesive or a temperature setting adhesive, as previously described) to a surface of the first 901 and/or second 902 flexible sections, aligning the first flexible section 901 with the second flexible section 902 to form a stack with the capacitive elements 904 facing one another, and applying pressure and/or heat to create the bond. To form the rigid regions 911, 912 of the structure, a rigid material 907 (such as FR-4 or another glass-reinforced epoxy laminate) is deposited on one or both external surfaces of the stack. It is important, however, that a region 908 of the surface is kept free from rigid material 907 in order to maintain flexibility of the stack at this region. Additional layers of protective material 909 (such as polyimide) may be deposited on top of the rigid material 907 to isolate the rigid material 907 from the external environment. After deposition, the power supply 910 terminals can be connected to the electrically conductive layers 903 at the rigid regions 911, 912 of the structure for charging the capacitive elements 904.

A second method of assembly is shown in FIG. 9b. This time, rather than building the structure up from the flexible sections, one or more pre-fabricated rigid-flex circuit boards are used. This method may be performed using either one rigid-flex circuit board and one FPC board, or two rigid-flex circuit boards. Each of the circuit boards 913, 914 comprises an electrically conductive layer 903 and a capacitive element 904. The capacitive elements 904 may be formed as described with reference to FIG. 2. The circuit boards 913, 914 are then attached using an adhesive 906. As before, the circuit boards 913, 914 must be aligned prior to bonding so that the capacitive elements 904 are facing one another. After bonding, the power supply 910 terminals can be connected to the electrically conductive layers 903 at the rigid regions 911, 912 of the structure for charging the capacitive elements 904.

In another embodiment (shown in FIG. 9c), a flexible section of material 916 may be attached between the rigid regions 911, 912 of a pre-fabricated rigid-flex circuit board 917 to provide the second capacitive element 904, rather than combining first and second pre-fabricated circuit boards 913, 914. The flexible region 915 of the rigid-flex circuit board 917 and the attached flexible section 916 each comprise an electrically conductive layer 903 and a capacitive element 904. The capacitive elements 904 may be formed as described with reference to FIG. 2. In this embodiment, however, although the rigid regions 911, 912 of the circuit board 917 each comprise first 903 and second 918 electrically conductive layers, only the first electrically conductive layer 903 is common to both rigid regions 911, 912 and the flexible region 915. In order to provide power to the capacitive element 904 of the attached flexible section 916, therefore, electrical contact must be established between the second electrically conductive layer 918 of the circuit board 917 and the electrically conductive layer 903 of the attached flexible section 916. In practice, this may be achieved by including a metallic interconnector 919 in the rigid regions 911, 912 of the circuit board as illustrated. After electrical contact has been established, the power supply 910 terminals can be connected to the electrically conductive layers 903, 918 at the rigid regions 911, 912 of the structure for charging the capacitive elements 904.

A final embodiment is shown in FIG. 9d. In this embodiment, a single pre-fabricated rigid-flex circuit board 920 is required. The circuit board 920 comprises two rigid regions 911, 912 electrically connected by a flexible region 915, the rigid regions 911, 912 and flexible region 915 sharing a common electrically conductive layer 903. Whilst the rigid-flex circuit board 920 may comprise more than one common electrically conductive layer 903, only one is required. Rather than attaching another section of material 916 or circuit board 914 to the existing board 920 to provide the second capacitive element 904 and electrically conductive layer 903, both capacitive elements 904 are added to one side of the flexible region 915, and the circuit board 920 is bent about the flexible region 915 such that the capacitive elements 904 are facing one another. In this embodiment, the different ends 921, 922 of the flexible region 915 constitute the first and second sections 804, 805 of the supercapacitor structure. To charge the supercapacitor, the positive and negative terminals of the power supply 910 may be connected to the electrically conductive layer 903 of the first 911 and second 912 rigid regions, respectively.

Rather than using a rigid material to stiffen the rigid regions of the circuit board, the number and/or thickness of the electrically conductive and electrically insulating layers may be increased in these regions to provide greater rigidity. Furthermore, the structure may also incorporate one or more of the following: a cover layer, an electromagnetic shield layer, a thermal protection layer, and an organic surface protection layer, which may also increase the rigidity of the structure. Any of the above-mentioned layers may be incorporated within the rigid or flexible regions of the circuit board.

The structure may also comprise an electrical connector (as described with respect to FIGS. 5 and 6) between the electrically conductive layers of the first and second sections to enable a flow of electrical charge from the capacitive elements to the electrical components when the apparatus discharges. The electrical components themselves may be physically and electrically connected (e.g. by surface mounting) to the rigid and/or flexible regions of the circuit board. The electrical connector may comprise an electrically conductive adhesive (such as an anisotropic conductive adhesive or a conductive pressure setting adhesive) or may comprise a metallic interconnector (such as vertical interconnect access, VIA, connector). Where an electrically conductive adhesive is used to provide the electrical connection, the electrically conductive adhesive may also be used to seal the first and second sections together to contain the electrolyte within the chamber. Combining the sealing and connection procedures simplifies the fabrication process. Furthermore, the structure may also comprise a switching mechanism (not shown) to make and break the electrical connection between the first and second sections (as described with respect to FIG. 5).

One advantage of the embodiment shown in FIG. 9d is that the electrically conductive layer extends from one capacitive element to the other, thereby negating the need to provide an additional electrical connector in order to discharge the supercapacitor and route power to the electrical components. A switching mechanism is required to make and break the electrical connection, however, otherwise the charge will simply flow around the circuit between the terminals of the power supply without being stored at the capacitive elements.

In each of the example embodiments described above, the presence of the supercapacitor (chamber) within the flexible region may increase the rigidity of the flexible region. In some situations this may be beneficial. For example, in flexible circuit boards, stiffeners are sometimes added to minimise shock and vibration of the circuit board during assembly and/or operation of the device. These vibrations can damage the electrically conductive traces and is therefore an important consideration.

As previously mentioned, the working voltage of a supercapacitor is limited by the breakdown voltage of the electrolyte. There are two types of electrolyte typically used in supercapacitors—aqueous electrolytes and organic electrolytes. The maximum voltage for supercapacitor cells that use aqueous electrolytes is the breakdown voltage of water, ˜1.1V, so these supercapacitors typically have a maximum voltage of 0.9V per cell. Organic electrolyte supercapacitors are rated in the range of 2.3V-2.7V per cell, depending on the electrolyte used and the maximum rated operating temperature. In order to increase the working voltage of a supercapacitor, several supercapacitor cells may be connected in series.

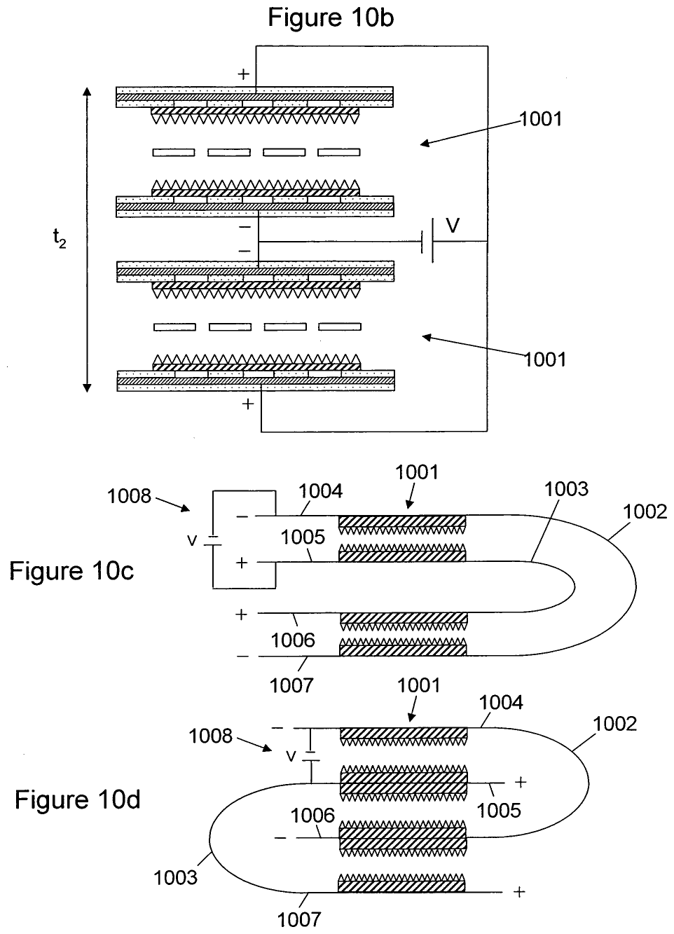

FIG. 10a shows two supercapacitors 1001 connected in series. The supercapacitors may be integrated within an FPC or rigid-flex structure. In this configuration, the total capacitance and maximum working voltage are given by 1/Cₜₒₜₐₗ=1/C₁+1/C₂ and VₘₐₓV₁+V₂, respectively. Therefore, although the working voltage is increased relative to a single supercapacitor 1001, the capacitance of the stack is reduced. The capacitance may be increased by connecting the supercapacitors 1001 in parallel, as shown in FIG. 10b. In this configuration, the total capacitance and maximum working voltage are given by Cₜₒₜₐₗ=C₁+C₂ and Vₘₐₓ=V₁=V₂, respectively. Therefore, although the capacitance of the stack is increased, the working voltage remains the same as that of a single supercapacitor 1001. A disadvantage of stacking the supercapacitors 1001, however, is the increase in thickness, t₂, of the structure which reduces its flexibility.

FIGS. 10c and 10d show how two circuit boards may combined in origami flex form to create a stack of integrated supercapacitors. The flexible circuit boards may be flexible (FPC) circuit boards as illustrated in FIG. 6c, or rigid-flex circuit boards as illustrated in FIG. 9d. In the latter case, the rigid-flex circuit boards would be bent about their flexible regions.

In FIG. 10c, first 1002 and second 1003 circuit boards, each comprising at least two capacitive elements 1001, are positioned one on top of the other such that the capacitive elements 1001 on the first circuit board 1002 are facing the capacitive elements 1001 on the second circuit board 1003. The structure is then bent around onto itself to form a C-shaped stack of supercapacitors. In this configuration, the capacitive elements 1001 are formed on the first 1004, 1005 and second 1006, 1007 ends of each circuit board 1002, 1003, thereby providing a two-capacitor stack. As described previously, the first 1002 and second 1003 circuit boards would need to be sealed together to hold the capacitive elements 1001 in position, and further sealed to form chambers around each pair of capacitive elements 1001 within which the separators and electrolyte (not shown) are contained. The sealing procedures may be combined as a single procedure, or may be performed as separate procedures. The terminals of the power supply 1008 are then connected to the first 1002 and second 1003 circuit boards to allow charging of the capacitive elements 1001. In this configuration, an electrical connector with switch (not shown) is required to connect the first 1002 and second 1003 circuit boards in order to discharge the capacitive elements 1001 and power the electrical components (not shown). An electrically conductive adhesive (e.g. anisotropic conductive adhesive, pressure sensitive adhesive or pressure sensitive adhesive) may be used to seal the first 1002 and second 1003 circuit boards together and form the electrical connector.

Furthermore, the electrical components may be electrically connected (e.g. surface mounted) to either or both of the circuit boards 1002, 1003.

In FIG. 10d, the first 1002 and second 1003 circuit boards are configured such that the first end 1005 of the second circuit board 1003 is positioned between the first 1004 and second 1006 ends of the first circuit board 1002 to form an S-shaped stack of supercapacitors. In this configuration, three capacitive elements 1001 are formed on each circuit board 1002, 1003 to provide a three-capacitor stack. Again, the terminals of the power supply 1008 are connected to the first 1002 and second 1003 circuit boards to allow charging of the capacitive elements 1001.

To test the behaviour of the supercapacitors, cyclic voltammetry experiments were performed using a 5 cm²-area supercapacitor with a 1M solution of tetraethylammonium tetrafluoroborate in acetonitrile as the electrolyte. Cyclic voltammetry is a type of potentiodynamic electrochemical measurement which involves increasing the electrode potential linearly with time whilst measuring the current. This ramping is known as the experiment scan rate (V/s). In this case, a scan rate of 50 mV/s was used. Once the voltage reaches a set potential, the potential ramp is inverted. This inversion is usually performed a number of times during a single experiment. The current is then plotted against the applied voltage to give the cyclic voltammogram trace.

This experiment produced a rectangular trace (not shown) indicating good capacitor behaviour. Furthermore, during the experiment the applied voltage was increased to 2.7V without degradation of the supercapacitor performance.

Following this, the effect of varying the number of separator layers in the supercapacitor was studied. Again, these experiments were performed using 5 cm²-area supercapacitors with a 1M solution of tetraethylammonium tetrafluoroborate in acetonitrile as the electrolyte. It was found that an increase in the number of separator layers from 1 to 2 caused an increase in capacitance and a decrease in ESR. The same trend was observed when the number of separator layers was increased from 2 to 3. This may be attributed to a greater number of pores available to accommodate the ionic species in the electrolyte, which may allow more ions to interact with the high surface material. When the number of separator layers was increased beyond 3, however, there was no further change in capacitance.

Charge-discharge (V) curves (not shown) cycled at ±1 mA (+1 mA for charging the cell and −1 mA for discharging the cell, each cycle lasting 20 secs) revealed capacitances of between 250-649mF with ESRs of between 5.35-1.8Ω. The capacitance was deduced from the slope of the discharging curve where C=I/(dV/dt), C is the capacitance of the cell in farads, I is the discharge current in amperes, and dV/dt is the slope in volts per second. The direct current ESR was calculated using ESR=dV/dI, where dV is the voltage drop at the beginning of the discharge in volts, and dI is the current change in amperes.

The effect of varying the high surface material in the supercapacitor was also studied. Three formulations of high surface material were tested: 97% activated carbon and 3% PTFE (binder), (ii) 87% activate carbon, 10% carbon nanotubes and 3% PTFE, and (iii) 77% activated carbon, 20% carbon nanotubes and 3% PTFE. Again, these experiments were performed using 5 cm²-area supercapacitors with a 1M solution of tetraethylammonium tetrafluoroborate in acetonitrile as the electrolyte.

Cyclic voltammetry experiments produced rectangular traces (not shown) for each sample, indicating good capacitor behaviour. Furthermore, charge-discharge (V) curves (not shown) cycled at ±1 mA revealed respective capacitances of 476, 500 and 649mF with respective ESRs of 2.3, 1.8 and 1.8Ω. The increase in capacitance and decrease in ESR with nanotube content may be attributed to the high surface area and high electrical conductivity of the carbon nanotubes.

As mentioned in the background section, multimedia enhancement modules in portable electronic devices often require fast power transients. This is particularly true of power amplifier modules for RF transmission, which may require over 3 W of power during transmission peaks. This power is typically supplied from a battery, with the current travelling from the battery, through conductive tracks on the transmission line substrate, to the power amplifier which drives the antenna. The further the battery is from the power amplifier, the greater the power dissipated in the transmission line impedance. To minimize this loss, the power source should therefore be placed as closely as possible to the power amplifier. Current state-of-the-art devices employ discrete (aluminium-plastic bag) supercapacitors between the battery and the power amplifier. Supercapacitors can charge and discharge quickly, and when combined with a battery, can remove the instantaneous energy demands that would normally be placed on the battery. Despite these advantages, however, the location of discrete supercapacitors on the circuit board is limited by their size and shape.

An antenna is a transducer which transmits and/or receives electromagnetic waves, and comprises an arrangement of one or more electrical conductors (usually called “elements”). During transmission, an alternating current is created in the elements by applying a voltage at the antenna terminals, causing the elements to radiate an electromagnetic field. During reception, an electromagnetic field from another source induces an alternating current in the elements and a corresponding voltage at the antenna terminals.

Several critical parameters affect an antenna's performance and can be adjusted during the design process. These include resonant frequency, impedance, antenna gain, radiation pattern, polarization, efficiency, and bandwidth. Transmission antennas may also have a maximum power rating, whilst receiving antennas differ in their noise reduction properties.

There are at least two main types of antenna currently in use in mobile phones—internal monopole antennas, and planar inverted-F (PIFA) antennas. Unlike the wire antennas of older mobile phones, for example retractable or non-retractable external helices, monopoles or whip antennas, internal monopole and PIFA antennas are internal to the device. The internal monopole and PIFA antennas may be fabricated as planar antennas, which may be advantageous in portable electronic devices because they can be fabricated directly onto circuit boards, have a low cost, a low profile and are simple to manufacture. Alternatively, these internal antennas may be fabricated using other materials, for example, wire formed on plastic frames or moulded into plastic housings. Internal antennas can be substantially planar or they may be disposed in three dimensions over the length of the antenna element. Furthermore, internal antennas may be curved in three dimensions.

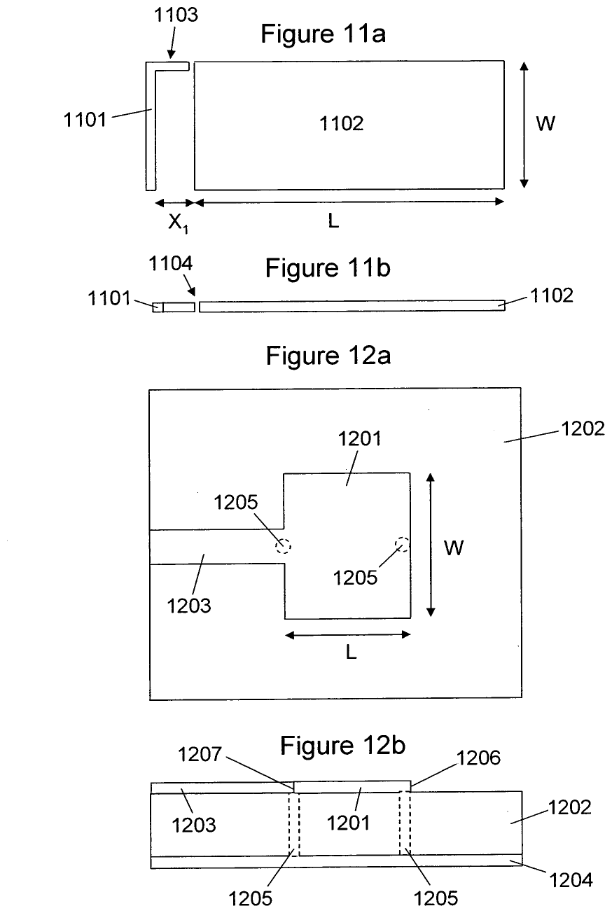

As an example, FIGS. 11a and 11b illustrate a planar monopole antenna in plan view and side view, respectively. A monopole antenna 1101 has an omnidirectional and linearly polarized radiation pattern, and may be formed by replacing the bottom half of a dipole antenna with a ground plane 1102. A monopole antenna 1101 uses the ground plane 1102 as a reference plane, and is electrically connected to an RF feed 1103. In this way, therefore, the ground plane 1102 and monopole antenna 1101 represent the bottom and top halves of a dipole arm, respectively. It should be noted, however, that the monopole antenna 1101 is not electrically connected to the ground plane 1102, as illustrated by the break 1104 at the RF feed 1103. The monopole antenna 1101 and ground plane 1102 may be co-linear, but in FIGS. 11a and 11b, the antenna 1101 has been bent through 90°. This is because the space available inside mobile phones is limited, so the antenna 1101 must be twisted and turned (sometimes several times) in order to achieve the required electrical length. It should be appreciated that the electrical length is related to the physical length of an antenna as is known in the art, and that the electrical length depends upon the electrical characteristics, namely the dielectric constant and loss tangent, of the materials surrounding, capacitively coupling and physically touching the antenna elements, including and not limited to dielectric materials, other conductive objects, non-conductive mechanical supports, printed wiring boards, flexi-circuits, etc.

As shown in FIG. 11a, the antenna 1101 is spaced apart from the ground plane 1102 (X₁ is typically on the order of several millimeters) to prevent inference from electromagnetic fields generated by current flowing through the adjacent conductor 1102. In practice, the antenna 1101 will usually be spaced apart in three dimensions from any conductive parts disposed around it. The electrical and/or physical length, L, in FIG. 11a determines the operational frequency in conjunction with the length (W+X₁) of the antenna 1101 and RF feed 1103. Furthermore, the width (W) of the ground plane 1102 is sufficiently large to minimize impedance.

The PIFA antenna is based on the structure of a microstrip (or patch) antenna. A standard microstrip antenna produces linearly polarized electromagnetic fields, and is shown in plan view and side view in FIGS. 12a and 12b, respectively. Microstrip antennas are usually fabricated on top of a dielectric substrate 1202, and comprise a planar antenna element 1201 which is fed by a narrow (microstrip) transmission line 1203. The bottom surface of the substrate 1202 is coated with a continuous layer of conductive metal to form the ground plane 1204. The length (L) and width (W) of the antenna element 1201 determine the frequency of operation, and should be equal to one half of the wavelength within the dielectric substrate 1202.

Antenna designers often look to improve performance. One method used in microstrip antennas is to introduce a shorting pin 1205 between the antenna 1201 and the ground plane 1204 in at least one location. By taking a quarter-wavelength antenna 1201 (i.e. same as microstrip antenna 1201 of FIGS. 12a and 12b but with half the length L), and adding a shorting pin 1205 at the end of the antenna 1201, the current at the end 1206 of the antenna 1201 is no longer zero. As a result, the quarter-wavelength antenna has the same current-voltage distribution as a half-wavelength antenna, but is reduced in size by 50%. The shorting pin 1205 may alternatively be added at the feed 1207 to a microstrip antenna 1201. This has the effect of introducing a parallel inductance to the antenna 1201 impedance, which can be used to modify the resonant frequency of the antenna 1201.

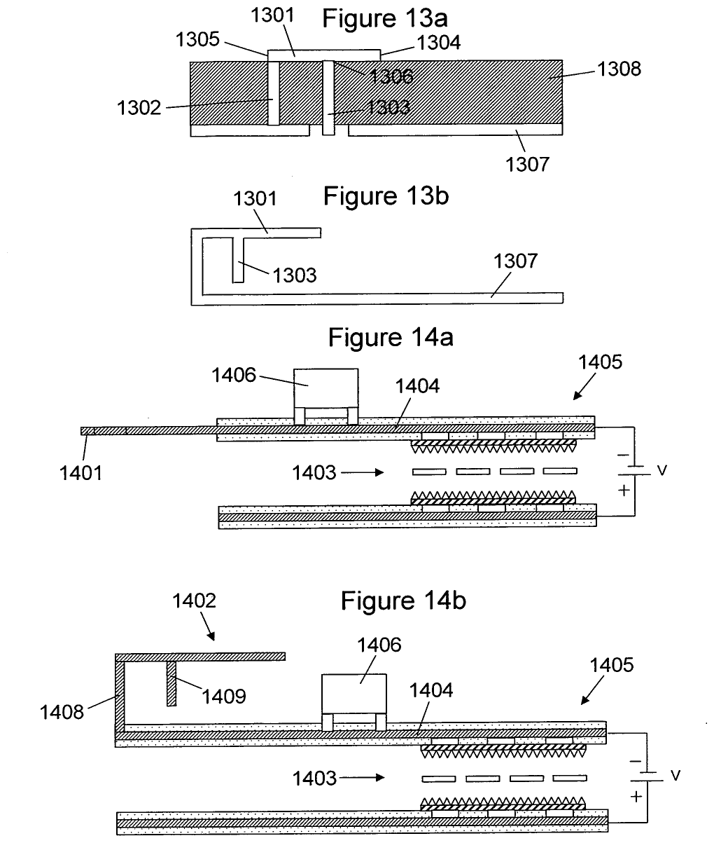

The PIFA antenna (FIG. 13a) is a microstrip antenna which resembles an inverted “F” (hence the name). These antennas are popular because of their low profile and omnidirectional radiation pattern. The PIFA uses a shorting pin 1302 at the end of the antenna 1301 (as discussed above), and the feed 1303 is connected to the antenna 1301 somewhere between the open 1304 and shorted 1305 ends. The contact position 1306 of the feed 1303 affects the input impedance. Rather than separating the antenna 1301 from the ground plane 1307 using an insulating substrate 1308, some PIFA antennas use air instead (FIG. 13b). In these antennas, the metal used to form the ground plane 1307 may be bent back on itself to form the antenna 1301, thereby negating the need for a shorting pin 1302.

By using the FPC or rigid-flex integrated supercapacitor described herein, it is possible to place the antenna and power amplifier in close proximity to the power source. In this way, power loss in the transmission line can be minimized.

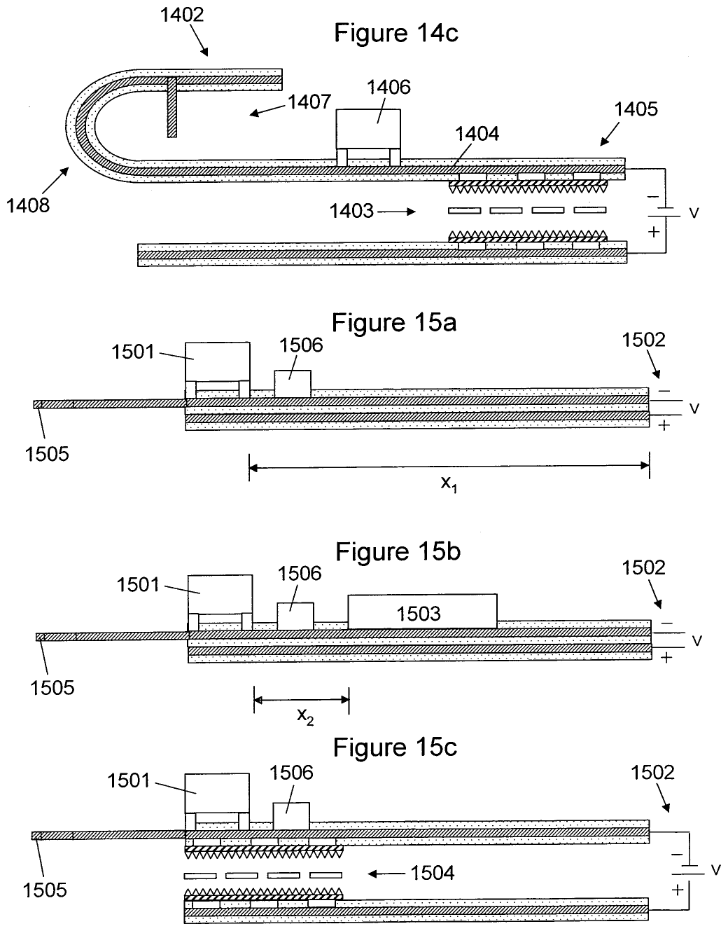

FIGS. 14a and 14b illustrate schematically a planar monopole 1401 and planar inverted-F 1402 antennas integrated with a supercapacitor 1403. In these exemplary embodiments, the electrically conductive layer 1404 of the first circuit board 1405 serves as the reference ground plane for the antenna 1401, 1402. This configuration maximises the use of the electrically conductive layer 1404 and therefore provides a more compact structure. In both example embodiments, the power amplifier 1406 may be physically attached to the first circuit board 1405 (electrically connected to the electrically conductive layer 1404) and positioned in such a way as to minimise the distance to the supercapacitor 1403.

The monopole 1401 or PIFA antenna 1402 may simply be an extension of the electrically conductive layer 1404, or a separate conductive element which has been connected to the electrically conductive layer 1404. Rather than attaching a shorting pin 1408 between the PIFA antenna 1402 and the electrically conductive layer 1404 of the first circuit board 1405, however, the first circuit board 1405 may be bent around onto itself to define the air cavity 1407 (FIG. 14c). In this embodiment, the electrically conductive layer 1404 serves both as the antenna 1402 and the shorting pin 1408. As well as simplifying fabrication, this configuration reduces contact losses otherwise introduced by pogo-pins (or alternative connectors). In other embodiments, the RF feed 1409 may also be an integral part of the electrically conductive layer 1404. In this scenario, the RF feed 1409 may be formed as an adjacent track next to and insulated from the shorting pin 1408. Other tracks could also be included. For example, if the antenna 1402 was active and not passive, other signal and control lines may be required in the electrically conductive layer 1404 for band switching electronics.

Whilst monopole 1401 and PIFA 1402 antennas have been described above, a person skilled in the art of antennas will appreciate that other types of antenna, such as planar inverted-L, loop, dipole, and inverted-F antennas, may also be integrated within the supercapacitor structure described herein.

For greater control of the resonance peak, the ground plane of an antenna may be electrically connected to other grounded parts of the device (which may be a mobile phone, PDA, or laptop etc). In this respect, the first circuit board 1405 may be connected to, or form part of, the device motherboard. When a rigid-flex circuit board is used, one rigid region of the circuit board may constitute the motherboard, with the other rigid region constituting the RF module. In this configuration, the flexible region connecting the two rigid regions (within which the supercapacitor structure is formed) could provide the electrical contact. In another embodiment, the RF module may be formed on the flexible region, thereby allowing the second rigid region to be used as another device module. When two FPC boards are used, connectors may be used to provide the electrical connection between the first circuit board 1405 and the device motherboard. On the other hand, if the first circuit board 1405 forms part of the device motherboard, the ground connection continuity is increased. This has the advantage of reducing unwanted resonances and emission associated with electrical discontinuities.

FIGS. 15a, 15b and 15c respectively show the variation in distance (x₁, x₂) between the power amplifier and the power source depending on whether a battery 1502, a discrete supercapacitor 1503, or an integrated supercapacitor 1504 is used to power the antenna 1505. In the example embodiments shown in FIGS. 15a and 15b, an additional capacitor 1506 (smoothing capacitor) may also be provided to supplement the power source 1502, 1503. This is because the battery 1502 and supercapacitor 1503 are positioned further away from the power amplifier 1501 and are therefore incapable of responding to the power demands of the antenna 1505/amplifier 1501 quickly enough. Furthermore, given the time it takes to recharge a battery 1502 or supercapacitor 1503, these power sources are not always capable of delivering power in high frequency bursts. In contrast, the smoothing capacitor 1506 is smaller in size and can be placed in close proximity to the power amplifier 1501. As a result, the smoothing capacitor 1506 can be recharged in a shorter time, and is able to deliver power (albeit less that a battery 1501 or supercapacitor 1503) more quickly. In the embodiment shown in FIG. 15c, the smoothing capacitor 1506 is needed only to supplement the integrated supercapacitor 1504 frequency response limitations, and not for layout purposes.

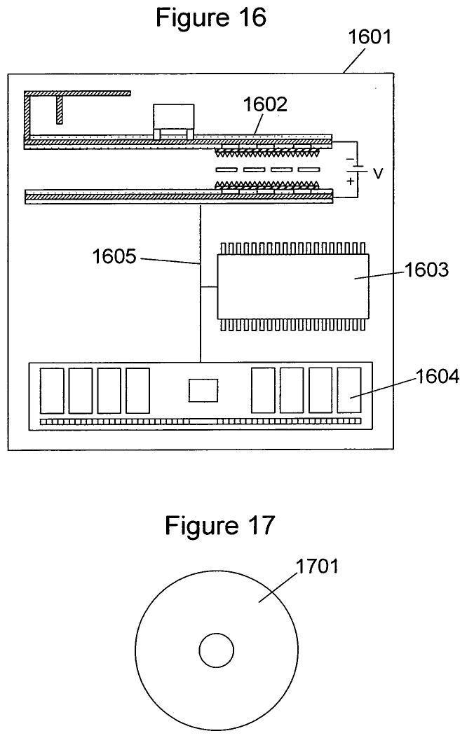

FIG. 16 illustrates schematically an electronic device 1601 comprising an antenna-integrated supercapacitor 1602. The device also comprises a processor 1603 and a storage medium 1604, which may be electrically connected to one another by a data bus 1605. The device 1601 may be a portable telecommunications or electronics device.

The antenna-integrated supercapacitor 1602 forms part of an RF module for the device 1601. The supercapacitor itself is used to store electrical charge for powering the various components of the RF module (e.g. power amplifier and smoothing capacitor).

The processor 1603 is configured for general operation of the device 1601 by providing signalling to, and receiving signalling from, the other device components to manage their operation. In particular, the processor 1603 is configured to provide signalling to control the charging and discharging of the supercapacitor 1602. Typically, the supercapacitor 1602 will discharge whenever the antenna/power amplifier requires a short current burst. For example, a short burst of current will be required whenever the user of the device 1601 wishes to transmit information (e.g. text message, telephone call etc) from his/her device 1601 to a remote device. In this scenario, the processor 1603 provides signalling to instruct the supercapacitor 1602 to discharge and provide the antenna/power amplifier with the required current. After the supercapacitor 1602 has discharged, the processor 1603 instructs the supercapacitor 1602 to recharge using a connected battery (or other power supply). The use of a supercapacitor 1602 therefore removes the instantaneous energy demands that would normally be placed on the battery. The processor 1603 may provide signalling to operate a switch, operation of the switch configured to break and make the electrical connection between the capacitive elements to cause charging and discharging of the supercapacitor 1602, respectively.

The storage medium 1604 is configured to store computer code required to operate the apparatus, as described with reference to FIG. 17. The storage medium 1604 may also be configured to store device settings. For example, the storage medium 1604 may be used to store specific current/voltage settings for the various electrical components (e.g. the components of the RF module). In particular, the storage medium 1604 may be used to store the voltage setting of the supercapacitor 1602. The processor 1603 may access the storage medium 1604 to retrieve the desired information before instructing the supercapacitor 1602 to recharge using the battery. The storage medium 1604 may be a temporary storage medium such as a volatile random access memory. On the other hand, the storage medium 1604 may be a permanent storage medium such as a hard disk drive, a flash memory, or a non-volatile random access memory.

FIG. 17 illustrates schematically a computer/processor readable medium 1701 providing a computer program according to one embodiment. In this example, the computer/processor readable medium 1701 is a disc such as a digital versatile disc (DVD) or a compact disc (CD). In other example embodiments, the computer/processor readable medium 1701 may be any medium that has been programmed in such a way as to carry out an inventive function. The computer/processor readable medium 1701 may be a removable memory device such as a memory stick or memory card (SD, mini SD or micro SD).

The computer program may control the power supply of an amplifier configured to drive an antenna using an apparatus, the apparatus comprising first and second circuit boards, and an antenna for transmitting and/or receiving electromagnetic signals, the first and second circuit boards each comprising an electrically conductive layer, and a capacitive element configured to be charged and discharged, the apparatus configured such that a chamber is defined between the first and second circuit boards with the capacitive elements contained therein and facing one another, the chamber containing an electrolyte, wherein the electrically conductive layer of the first circuit board is configured to serve as a reference ground for the antenna, and wherein discharge of the capacitive elements is configured to provide a flow of current to an amplifier configured to drive the antenna, the computer program comprising code configured to control discharge of the capacitive elements to provide a flow of current to the amplifier configured to drive the antenna.

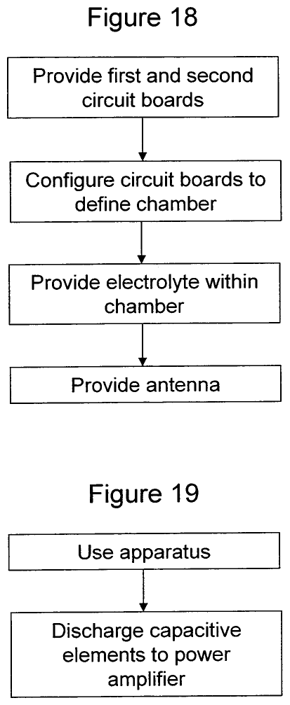

The key stages of the method used to assemble an antenna integrated with a supercapacitor are illustrated schematically in FIG. 18. The key stages of the method used to power an antenna using an integrated supercapacitor are illustrated schematically in FIG. 19.

It will be appreciated to the skilled reader that any mentioned apparatus/device/server and/or other features of particular mentioned apparatus/device/server may be provided by apparatus arranged such that they become configured to carry out the desired operations only when enabled, e.g. switched on, or the like. In such cases, they may not necessarily have the appropriate software loaded into the active memory in the non-enabled (e.g. switched off state) and only load the appropriate software in the enabled (e.g. on state). The apparatus may comprise hardware circuitry and/or firmware. The apparatus may comprise software loaded onto memory. Such software/computer programs may be recorded on the same memory/processor/functional units and/or on one or more memories/processors/functional units.

In some example embodiments, a particular mentioned apparatus/device/server may be pre-programmed with the appropriate software to carry out desired operations, and wherein the appropriate software can be enabled for use by a user downloading a “key”, for example, to unlock/enable the software and its associated functionality. Advantages associated with such example embodiments can include a reduced requirement to download data when further functionality is required for a device, and this can be useful in examples where a device is perceived to have sufficient capacity to store such pre-programmed software for functionality that may not be enabled by a user.

It will be appreciated that the any mentioned apparatus/circuitry/elements/processor may have other functions in addition to the mentioned functions, and that these functions may be performed by the same apparatus/circuitry/elements/processor. One or more disclosed aspects may encompass the electronic distribution of associated computer programs and computer programs (which may be source/transport encoded) recorded on an appropriate carrier (e.g. memory, signal).

It will be appreciated that any “computer” described herein can comprise a collection of one or more individual processors/processing elements that may or may not be located on the same circuit board, or the same region/position of a circuit board or even the same device. In some example embodiments one or more of any mentioned processors may be distributed over a plurality of devices. The same or different processor/processing elements may perform one or more functions described herein.

With reference to any discussion of any mentioned computer and/or processor and memory (e.g. including ROM, CD-ROM etc), these may comprise a computer processor, Application Specific Integrated Circuit (ASIC), field-programmable gate array (FPGA), and/or other hardware components that have been programmed in such a way to carry out the inventive function.

The applicant hereby discloses in isolation each individual feature described herein and any combination of two or more such features, to the extent that such features or combinations are capable of being carried out based on the present specification as a whole, in the light of the common general knowledge of a person skilled in the art, irrespective of whether such features or combinations of features solve any problems disclosed herein, and without limitation to the scope of the claims. The applicant indicates that the disclosed example aspects/embodiments may consist of any such individual feature or combination of features. In view of the foregoing description it will be evident to a person skilled in the art that various modifications may be made within the scope of the disclosure.

While there have been shown and described and pointed out fundamental novel features as applied to different example embodiments thereof, it will be understood that various omissions and substitutions and changes in the form and details of the devices and methods described may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment may be incorporated in any other disclosed or described or suggested form or embodiment as a general matter of design choice. Furthermore, in the claims means-plus-function clauses are intended to cover the structures described herein as performing the recited function and not only structural equivalents, but also equivalent structures. Thus although a nail and a screw may not be structural equivalents in that a nail employs a cylindrical surface to secure wooden parts together, whereas a screw employs a helical surface, in the environment of fastening wooden parts, a nail and a screw may be equivalent structures.

1. An apparatus comprising first and second circuit boards, and an antenna for at least one of transmitting or receiving electromagnetic signals,
the first and second circuit boards each comprising an electrically conductive layer, and a capacitive element configured to be charged and discharged, the apparatus configured such that a chamber is defined between the first and second circuit boards with the capacitive elements contained therein and facing one another, the chamber containing an electrolyte,
wherein the electrically conductive layer of the first circuit board is configured to serve as a reference ground for the antenna, and
wherein discharge of the capacitive elements is configured to provide a flow of current to an amplifier configured to drive the antenna.

2. The apparatus of claim 1, wherein the apparatus comprises an amplifier configured to drive the antenna.

3. The apparatus of claim 2, wherein the amplifier is electrically connected to the electrically conductive layer of the first circuit board and positioned to minimise the distance between the capacitive elements and the amplifier.

4. The apparatus of claim 1, wherein the apparatus forms part of an electronic device, and wherein the electrically conductive layer of the first circuit board is electrically connected to at least one grounded part of the electronic device.

5. The apparatus of claim 4, wherein the electronic device comprises a motherboard, the first circuit board comprising part of the motherboard.

6. The apparatus of claim 1, wherein the antenna is one of the following: a monopole, dipole, loop, inverted-F, planar inverted-L, or planar inverted-F antenna.

7. The apparatus of claim 6, wherein the planar inverted-F antenna is one end of the first circuit board which has been bent around on itself to define a cavity.

8. The apparatus of claim 1, wherein one or both of the first and second circuit boards are flexible printed circuit boards, or flexible regions of a rigid-flex circuit board.

9. The apparatus of claim 1, wherein each capacitive element comprises a high surface area material.

10. The apparatus of claim 9, wherein each capacitive element comprises an electrically conductive region having a surface, the high surface area material disposed on the surface of each electrically conductive region, the respective surfaces/high surface area materials of the electrically conductive regions configured to face one another.

11. The apparatus of claim 9, wherein the high surface material comprises one or more of the following: activated carbon, carbon nanotubes, carbon nanohorns, carbon nanofibres and carbon nano-onions.

12. A portable electronic device comprising the apparatus of claim 1.

13. The portable electronic device of claim 12, wherein the portable electronic device is one or more of the following: a portable telecommunications device, circuitry for a portable telecommunications device, and a module for a portable telecommunications device.

14. (canceled)

15. A method of powering an amplifier configured to drive an antenna, the method comprising:
using an apparatus, the apparatus comprising first and second circuit boards, and an antenna for at least one of transmitting or receiving electromagnetic signals,
the first and second circuit boards each comprising an electrically conductive layer, and a capacitive element configured to be charged and discharged, the apparatus configured such that a chamber is defined between the first and second circuit boards with the capacitive elements contained therein and facing one another, the chamber containing an electrolyte,
wherein the electrically conductive layer of the first circuit board is configured to serve as a reference ground for the antenna, and
wherein discharge of the capacitive elements is configured to provide a flow of current to an amplifier configured to drive the antenna; and wherein the method comprises
discharging the capacitive elements to provide a flow of current to the amplifier configured to drive the antenna.

16. A computer program for controlling the power supply of an amplifier configured to drive an antenna using an apparatus, the apparatus comprising first and second circuit boards, and an antenna for at least one of transmitting or receiving electromagnetic signals,
the first and second circuit boards each comprising an electrically conductive layer, and a capacitive element configured to be charged and discharged, the apparatus configured such that a chamber is defined between the first and second circuit boards with the capacitive elements contained therein and facing one another, the chamber containing an electrolyte,
wherein the electrically conductive layer of the first circuit board is configured to serve as a reference ground for the antenna, and
wherein discharge of the capacitive elements is configured to provide a flow of current to an amplifier configured to drive the antenna,
the computer program comprising code configured to control discharge of the capacitive elements to provide a flow of current to the amplifier configured to drive the antenna.
